(19) United States
(12) Patent Application Publication
(10) Pub. No.: US 2008/0154539 A1
(43) Pub. Date: Jun. 26, 2008

(54) SYSTEM AND METHOD FOR MEASURING THE WHEELBASE OF A RAILCAR

(76) Inventor: John Edward Borntraeger, The Villages, FL (US)

Correspondence Address: BEUSSE WOLTER SANKS MORA & MAIRE, P.A., 390 NORTH ORANGE AVENUE, SUITE 2500, ORLANDO, FL, 32801, US

(21) Appl. No.: 11/862,445

(22) Filed: Sep. 27, 2007

Related U.S. Application Data
(60) Provisional application No. 60/870,899, filed on Dec. 20, 2006.

(51) Int. Cl. G01B 7/14; G01R 27/00

(52) U.S. Cl. 702/158; 324/649

(57) ABSTRACT

A system for measuring the wheelbase of a railcar that includes a track having a first rail positioned parallel to second rail. An alternating electrical circuit having a feed point is located on the first rail at which an electrical alternating current is introduced to the first rail. A shunt extends from the first rail to the second rail and a receiver positioned on the second rail detects an impedance in the circuit and transmits a signal indicative of the impedance detected. A controller receives a signal from the receiver, and accesses a database having data representative of a plurality of impedance values. Each impedance value is associated with a distance an axle of a railcar is spaced from the receiver or feed point after having passed the shunt, which data is used to calculate a wheelbase of the railcar.

### CROSS-REFERENCE TO RELATED APPLICATIONS

This application claims priority to U.S. Provisional Application No. 60/870,899 filed Dec. 20, 2006, which is incorporated herein by reference in its entirety.

### BACKGROUND OF THE INVENTION

An embodiment of the invention is generally related to monitoring the motion of railcars in railroad yards, and, more particularly, to a system, method and computer-readable media for calculating, estimating or determining the wheelbase of a railcar traveling in a rail yard.

A classification yard, such as a hump yard, shunting yard and gravity yard, is a railroad yard at freight stations where a railcar may be separated from a train of cars on to one of several classification tracks. Railcars are pushed, or rolled down an incline as in a hump yard, to build momentum and speed to pass through a series of switches that direct the railcars to a predetermined classification track. Typically, the railcars are classified in accordance with a destination of the railcars.

Several parameters relative to the performance of a railcar in a classification yard are monitored. For example, the speed and acceleration are monitored so that a railcar may safely reach its destination and connect with other railcars. If a railcar is traveling to slow it may not connect with the other railcars, or may be hit from behind by a railcar traveling faster, possibly damaging or derailing the railcars. The speed and acceleration of a railcar is controlled in part by retarders positioned at various locations in the yard.

In addition, the wheelbase of a railcar may be calculated to determine, for example, if enough space is available on a classification track for a railcar to fit, and to avoid collisions with other cars. Classification yards are typically monitored using detectors mounted on, or adjacent to the railroad track and are linked with one or more control systems. These detectors may be positioned on tracks at various locations in a classification yard to monitor the location and speed of a railcar. The location of a railcar is critical, so the distance and speed a connecting railcar needs to travel may be accurately calculated, and so the car can be adequately protected (collision avoidance) during its movement.

The control systems for classification yards include databases that contain data relative to the railcars located in the yard. The data may include the wheelbase for a given railcar. This wheelbase data may, however, be unreliable for any number of reasons. The wheelbase is the distance from the first axle to the last axle of a railcar. Railcars typically have four axles, so the wheelbase is the distance measured from the first axle to the fourth axle. In addition, the data may include the overhang distance, which is the distance measured from the front axle or rear axle to the end of the car. Accordingly, if the control system knows where the first axle (or front axle) is located in the classification yard, the control system will know where the front and rear of the car is located because the data includes the distance from the first axle to the fourth axle, and the distance measured from the first and fourth axle to the respective car end (overhang).

Current control systems measure the wheelbase by first determining the speed and/or acceleration of the railcar at a given location. Such systems use one or more, typically three, stationary single point wheel detectors positioned adjacent to, or on, a track. A controller, then using multiple simultaneous algorithms, calculates the speed and acceleration of the car. Using this information, the distance from the first to the fourth axle (wheelbase) is then calculated.

However, the algorithms used to calculate the speed, acceleration and consequently the wheelbase, assume that the distance between the first and second axles is a standard length (5.5 feet). The accuracy of this speed measurement may be compromised by assuming the distance between these two axles is a standard length. The distance between the first and second axles of railcars may vary as much as six inches, resulting in speed errors. Errors in calculation of the speed and acceleration a railcar may result in railcar collisions, or even derailment in a classification yard.

### BRIEF DESCRIPTION OF THE INVENTION

An embodiment of a system for measuring the wheelbase of a railcar in a classification yard, includes a track having a first rail and a second rail that are parallel to one another. An alternating electrical circuit is provided having a feed point located on the first rail at which an electrical alternating current is introduced to the first rail, a shunt extending from the first rail to the second rail and a receiver on the second rail for detecting an impedance in the circuit and transmitting a signal indicative of an impedance detected. A controller is provided in communication with the receiver for receiving a signal from the receiver. The controller has a database with data representative of a plurality of impedance values and each impedance value is associated with a distance an axle of a railcar is spaced from the receiver or feed point after having passed the shunt, which data is used to calculate a wheelbase of the railcar.

### BRIEF DESCRIPTION OF THE DRAWINGS

A more particular description of the invention briefly described above will be rendered by reference to specific embodiments thereof that are illustrated in the appended drawings. Understanding that these drawings depict only typical embodiments of the invention and are not therefore to be considered to be limiting of its scope, the invention will be described and explained with additional specificity and detail through the use of the accompanying drawings.

FIG. 1 is a top schematic view of railcar approaching an impedance circuit in a classification yard.

FIG. 2 is a top schematic view of the railcar having entered the impedance circuit.

FIG. 3 is a top schematic view of the railcar having entered the impedance circuit and the first or front axle leaving the circuit.

FIG. 4 is a top schematic view of the railcar having entered the impedance circuit and the second axle leaving the circuit.

FIG. 5 is a top schematic view of the railcar having entered the impedance circuit and the third axle leaving the circuit.

FIG. 6 is a flow chart listing steps of the method for measuring the wheelbase of a railcar.

### DETAILED DESCRIPTION OF THE INVENTION

Before describing in detail the system for measuring the wheelbase of a railcar in accordance with embodiments of the invention, it should be observed that the present invention resides primarily in a novel combination of steps and system related to measuring a wheelbase of a railcar. Accordingly, these hardware components and method steps have been represented by conventional elements in the drawings, showing only those specific details that are pertinent to the present invention, so as not to obscure the disclosure with structural details that will be readily apparent to those skilled in the art having the benefit of the description herein.

Exemplary embodiments of the invention solve the problems in the art by providing a system, method, and computer software code, for measuring the wheelbase of a railcar. Persons skilled in the art will recognize that an apparatus, such as a data processing system, including a CPU, memory, I/O, program storage, a connecting bus, and other appropriate components, could be programmed or otherwise designed to facilitate the practice of the method of an exemplary embodiment of the invention. Such a system would include appropriate program means for executing the method.

Persons skilled in the art will recognize that an apparatus, such as a data processing system, including a CPU, memory, I/O, program storage, a connecting bus, and other appropriate components, could be programmed or otherwise designed to facilitate the practice of the method of the invention. Such a system would include appropriate program means for executing the method of the invention.

Also, an article of manufacture, such as a pre-recorded disk or other similar computer program product, for use with a data processing system, could include a storage medium and program means recorded thereon for directing the data processing system to facilitate the practice of the method of the invention. Such apparatus and articles of manufacture also fall within the spirit and scope of the invention.

In an embodiment shown in FIG. 1, the invention for a system and method for measuring the wheelbase of a railcar includes one or more impedance measuring track circuits 10. In reference to FIG. 1, there is shown a portion of a track 12 in a classification yard and an impedance circuit 10 integrated on the track 12. A railcar 13 is approaching the impedance circuit 10. The railcar 13 has four axles including a front or first axle 14, a second axle 15, a third axle 16 and rear or fourth axle 17. The impedance circuit 10 may be positioned at an entrance to the classification yard. For example, in a hump yard the impedance circuit may be positioned on the entrance hill, hump or incline.

The impedance circuit 10 includes a feed point 18 at which an alternating electrical current is introduced to the track 12 via an appropriate electrical source 11, a first rail 19 and a shunt 20 that is disposed laterally with respect to the first rail 19 and second rail 21 that is parallel to the first rail 19. The circuit 10 provides an electrical current from the shunt 20 to a receiver point 22 disposed on the second rail 21 opposite the feed point 18. The receiver point 22 is in electrical communication with a receiver 23 to monitor the impedance along the circuit 10. The receiver 23 is in electrical communication to the controller 24. In addition, the circuit 10 is closed by an electrical connection 25 from the alternating current source 11 to the controller 24. The length of the circuit may vary and may be as long as necessary so that all four axles 14, 15, 16 and 17 are between the feed point 18 and/or receiver point 22 and the shunt 20. Alternatively, the circuit 10 may be sized so that at any given time that a railcar 13 enters a circuit 10 at least two axles of the railcar 13 are disposed within the circuit 10. The hardware used in such as system is known to those skilled in the art and may include impedance systems incorporating the General Electric ElectroLogIXS hardware components.

The receiver 22 communicates with the controller 24 which is preferably a component of a classification yard monitoring system (not shown). The controller 24 includes a database having data relative to impedance levels or values that are associated with distance measurements. More specifically, the data may include impedance values or levels associated with a distance an axle is spaced from the receiver point 22 and/or feed point 18. In the present invention, the change in impedance across the circuit 10 as the railcar 13 advances on the track 12 is linear. Accordingly, before the first axle 14 of the railcar 13 passes over the shunt 20 the controller 24 interprets data received from the receiver 23 as a maximum impedance value Zₘₐₓ.

In an embodiment, the system 10 maintains a constant current when the shunting axle moves toward or away from the point. This means for example, that when an axle is moving from the shunt 20 toward the feed point 18 or receiver point 22, the impedance is decreasing, and the current then tends to increase, so the system 10 drops the voltage to maintain a “constant” current. It is in measuring this voltage change that the impedance variation is detected and calculated. The impedance variation (percentage) and the distance variation are linear. For example, the controller 24 may compare a signal received from the source 11 to a signal received from receiver 23. A signal from source 11 has a maximum impedance in comparison to the reduced impedance received from the receiver 23 as the shunting axle moves toward the receiver point 22 and/or feed point 18.

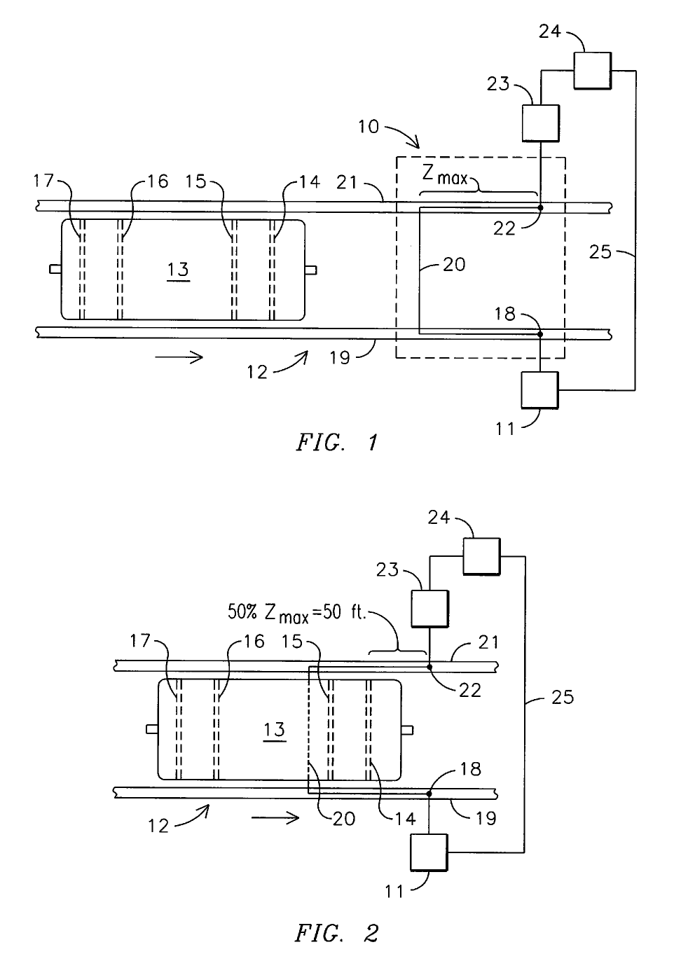

With respect to FIG. 2, and by way of example, the impedance circuit is 100 feet measured from the shunt 20 to the receiver point 22 or feed point 18. As the railcar 13 and axle 14 advance across the circuit 10, the receiver 23 detects the impedance level and transmits the data to the controller 24. The railcar 13 and first axle 14 are within the circuit 10 and positioned half way down the circuit 10. So the receiver 23 detects and transmits an impedance of one half the maximum impedance, which the controller 24 interprets as the axle 14 being located fifty feet from the receiver point 22.

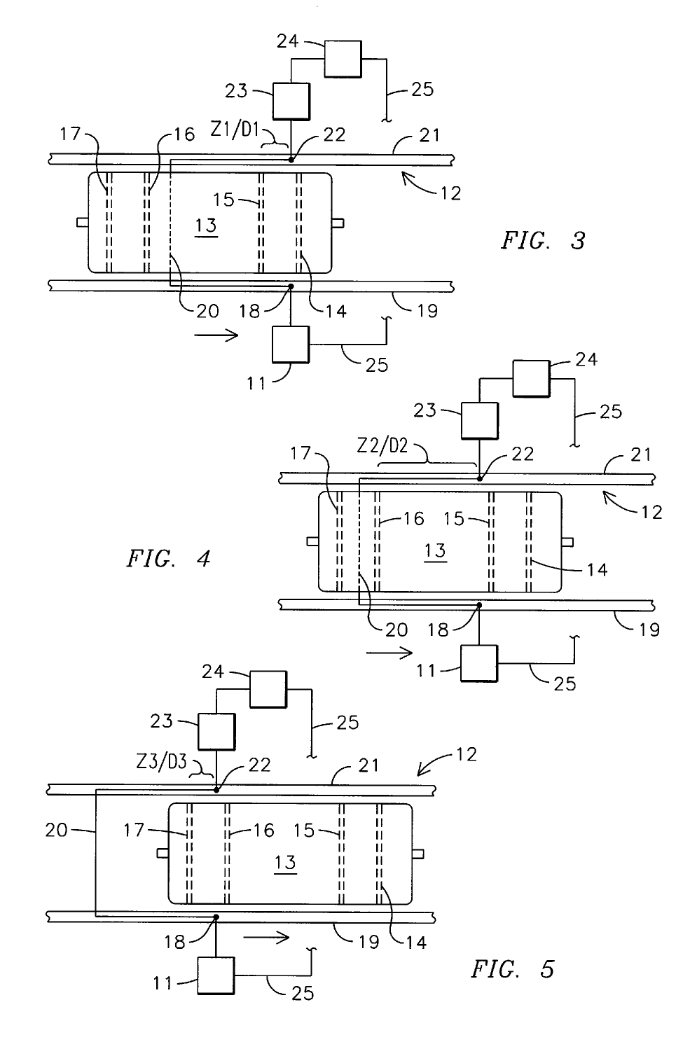

In regard to FIGS. 3 through 6, the system 10 and method are described. The receiver 23 continues to detect the impedance of the circuit 10, after the first axle 14 passes the receiver point 22. With respect to FIG. 3, the first axle 14 has passed the receiver point 22 and/or feed point 18. As described in step 30, FIG. 6, the receiver 23 detects the impedance on the circuit 10 resulting from the second axle 15 positioned within the circuit 10. The second axle 15 is positioned about 5.5 feet from the first axle 14. In step 31 the impedance is calculated as Z1/Zₘₐₓ. The impedance or variation of impedance Z1 of the circuit 10, detected immediately after the first axle 14 passes the receiver point 22 or feed point 18, is about 5.5% of the maximum impedance (Zₘₐₓ). Accordingly, the second axle 15 is a distance D1, or 5.5 feet from the first axle 14. As described in step 32, FIG. 6, the control system calculates the variation of the impedance as a percentage of the maximum impedance, Zₘₐₓ. A distance, D1, is then associated with the impedance variation.

Similarly as shown in FIG. 4, and steps 33 through 35 in FIG. 6, when the second axle 15 passes the receiver point 22, the impedance (or variation in impedance) Z2 detected is representative or indicative of the distance D2 that the third axle 16 is from the receiver point 22 and second axle 15. More specifically, in step 34 the variation (percentage) in impedance an impedance is calculated as Z2/Zₘₐₓ; and, in step 35 a distance D2 is associated with the impedance variance Z2.

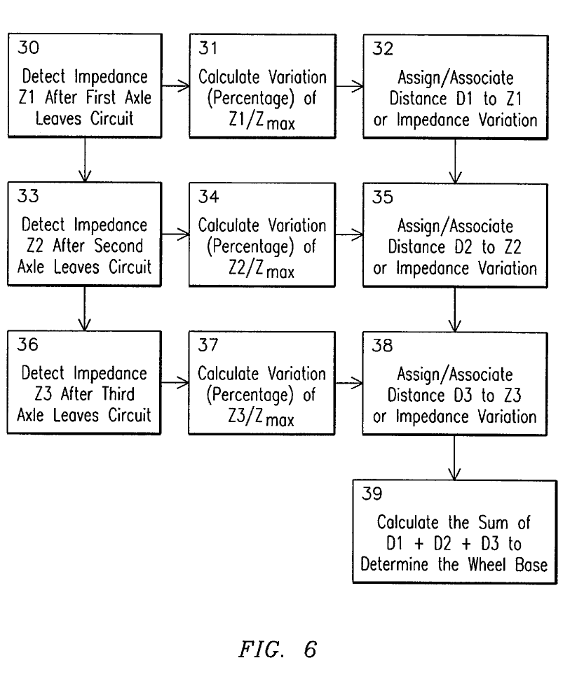

In FIG. 5, and steps 36 through 38 in FIG. 6, when the third axle 16 passes the receiver point 22, the impedance (or variation in impedance) Z3 detected (step 35) is representative or indicative of the distance D3 the fourth axle 17 is from the receiver point 22 and third axle 16. In step 37, the impedance variance is calculated as Z3/Zₘₐₓ; and, in step 38 a distance D3 is associated with the impedance variance Z3. As described in step 39 in FIG. 6, the sum of these three measurements D1, D2 and D3 is calculated to determine the distance from the first axle 14 to the fourth axle 17.

In this manner, the above described system and method obtains an accurate measurement of the wheelbase of the railcar 13 without making assumptions that may not be accurate. Similarly, the accurately determined distance D1 improves the speed measurements throughout the vehicle movement. The data relative to the wheelbase measurement may be used as described above in locating an end of a railcar, and/or determining if sufficient space is available or how much spaced is needed on a track for a given railcar. Typically monitoring systems may include databases having data relative to the identity of a given railcar, dimensions of the railcar and performance of the railcar. Such data may include the wheelbase for the railcar. However, the wheelbase for a railcar may change over time due for example to repairs to the railcar. Accordingly, the data generated by the above-described system and method may be used to update databases to include the accurate wheelbase measurement.

While the invention has been described with reference to an exemplary embodiment, it will be understood by those skilled in the art that various changes, omissions and/or additions may be made and equivalents may be substituted for elements thereof without departing from the spirit and scope of the invention. In addition, many modifications may be made to adapt a particular situation or material to the teachings of the invention without departing from the scope thereof. Therefore, it is intended that the invention not be limited to the particular embodiment disclosed as the best mode contemplated for carrying out this invention, but that the invention will include all embodiments falling within the scope of the appended claims. Moreover, unless specifically stated any use of the terms first, second, etc. do not denote any order or importance, but rather the terms first, second, etc. are used to distinguish one element from another.

What is claimed is:

1. A system for measuring the wheelbase of a railcar, comprising:
a track having a first rail and a second rail that are parallel to one another;
an alternating electrical circuit having a feed point located on the first rail at which an electrical alternating current is introduced to the first rail, a shunt extending from the first rail to the second rail and a receiver on the second rail for detecting an impedance in the circuit and transmitting a signal indicative of an impedance detected; and,
a controller in communication with the receiver for receiving a signal from the receiver, the controller having a database with data representative of a plurality of impedance values and each impedance value is associated with a distance an axle of a railcar is spaced from the receiver or feed point after having passed the shunt, which data is used to calculate a wheelbase of the railcar.

2. The system of claim 1 wherein the data includes data representative of first impedance value that is associated with a distance a second axle is spaced from a first axle, a second impedance value that is associated with a distance a third axle is spaced from the second axle and a third impedance value associate with a distance a fourth axle is spaced from the third axle and the controller is programmed to calculate the sum of the three distances to determine the wheelbase of a locomotive railcar.

3. The system of claim 1 wherein the data in the database includes a maximum impedance value that is associated with a length of the circuit from the shunt to the receiver or feed point, and the controller assigns a first distance to a first change in impedance when the first axle leaves the circuit as a distance the second axle is spaced from the first axle, and a second distance to a second change in impedance when the second axle leaves the circuit as a distance the third axle is spaced from the second axle, and a third distance to a third change in impedance when the third axle leaves the circuit as a distance the fourth axle is spaced from the third axle.

4. The system of claim 3 wherein the controller adds the first distance, second distance and third distance together to calculate the wheelbase of the railcar.

5. The system of claim 1 wherein the first rail and second rail are positioned on a hump in a classification yard.

6. A method for determining a wheelbase of a railcar located, comprising:
providing an alternating electrical circuit having a feed point located on a first rail of a track and at which an electrical alternating current is introduced to the first rail, a shunt extending from the first rail to a second rail that is parallel to the first rail and a receiver on the second rail;
detecting an impedance in the circuit as an axle on the railcar traverses the circuit;
transmitting to a controller a plurality of discrete signals each indicative of a detected impedance; and,
associating, in the controller, the detected impedance with a distance an axle of the railcar is spaced from a consecutive axle of the railcar having previously exited the circuit to determine the wheelbase of railcar.

7. The method of claim 6 wherein the step of detecting an impedance comprises the steps of detecting a first impedance when a first axle exits the circuit that is representative of a distance a second axle is spaced from the first axle, detecting a second impedance when the second axle exits the circuit that is representative of a distance a third axle is spaced from the second axle and detecting a third impedance when the third axle exits the circuit that is representative of a distance a fourth axle is spaced from the third axle.

8. The method of claim 7 comprising the step of calculating the sum of the three distances to determine the wheelbase of a railcar.

9. The method of claim 7 wherein the first rail and second rail are positioned on a hump of a classification yard.

10. A software program for determining a wheelbase of a railcar advancing on a track wherein on the track there is an alternating electrical circuit having a feed point located on a first rail of a track and at which an electrical alternating current is introduced to the first rail, a shunt extending from the first rail to a second rail that is parallel to the first rail and a receiver on the second rail, the program comprising;
a computer software module for detecting an impedance in the circuit;
a computer software module for transmitting to a controller a plurality of discrete signals wherein each signal is indicative of an impedance detected; and,
a computer software module for associating a detected impedance with a distance an axle of a railcar is spaced from a consecutive axle of the railcar having previously exited the circuit to determine the wheelbase of a railcar.

11. The software program of claim 10 wherein the module for detecting an impedance comprises one or more computer modules for detecting a first impedance when a first axle exits the circuit that is representative of a distance a second axle is spaced from the first axle, detecting a second impedance when the second axle exits the circuit that is representative of a distance a third axle is spaced from the second axle and detecting a third impedance when the third axle exits the circuit that is representative of a distance a fourth axle is spaced from the third axle.

12. The software program of claim 11 further comprising a computer software module for calculating the sum of the three distances to determine the wheelbase of a locomotive railcar.
